(19) United States
(12) Patent Application Publication
(10) Pub. No.: US 2024/0237437 A1
(43) Pub. Date: Jul. 11, 2024

(54) DISPLAY APPARATUS

(71) Applicant: Samsung Display Co., LTD., Yongin-si (KR)

(72) Inventor: Kyobum KUM, Yongin-si (KR)

(21) Appl. No.: 18/372,990

(22) Filed: Sep. 26, 2023

(30) Foreign Application Priority Data
Jan. 5, 2023 (KR) 10-2023-0001916

(51) Int. Cl. H10K 59/131; H05K 1/14; H05K 1/18

(52) U.S. Cl. CPC H10K 59/131; H05K 1/147; H05K 1/189; H05K 2201/10128

(57) ABSTRACT

A display apparatus includes: a display panel including a plurality of pixels, a main circuit board configured to transmit a signal to the display panel, and a connection circuit board arranged between the display panel and the main circuit board and having a lower surface to which one of the display panel and the main circuit board is attached and an upper surface to which another one of the display panel and the main circuit board is attached.

This application claims priority to Korean Patent Application No. 10-2023-0001916, filed on Jan. 5, 2023, and all the benefits accruing therefrom under 35 U.S.C. § 119, the content of which in its entirety is herein incorporated by reference.

### BACKGROUND

### 1. Field

One or more embodiments relate to display apparatuses.

### 2. Description of the Related Art

A display panel has been used for various purposes. Also, as the display panel has become thinner and lighter, their range of use has widened.

In general, the display panel is manufactured and then a circuit board is connected to the display panel. For example, in a tape automated bonding (“TAB”) mounting method, a circuit board is bonded to the display panel by using an anisotropic conductive film (“ACF”). Research has been conducted to reduce a dead space while expanding an area occupied by a display area in the display panel.

### SUMMARY

One or more embodiments include a display apparatus capable of minimizing a dead space and implementing a high-quality image. However, these problems are merely examples and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus includes: a display panel including a plurality of pixels, a main circuit board configured to transmit a signal to the display panel, and a connection circuit board arranged between the display panel and the main circuit board and having a lower surface to which one of the display panel and the main circuit board is attached and an upper surface to which another one of the display panel and the main circuit board is attached.

In an embodiment, the display panel and the main circuit board may at least partially overlap each other in a plan view.

In an embodiment, the connection circuit board may include a base film layer, a first conductive layer arranged on a lower surface of the base film layer, a second conductive layer arranged on an upper surface of the base film layer, and an insulating film layer exposing at least a portion of the first conductive layer and the second conductive layer.

In an embodiment, the first conductive layer and the second conductive layer may be electrically connected to each other through a through-hole defined in the base film layer.

In an embodiment, the base film layer and the insulating film layer may include polyimide (“PI”), and the first conductive layer and the second conductive layer may include copper (Cu).

In an embodiment, the connection circuit board may further include a first pad unit arranged under a first area of the first conductive layer exposed by the insulating film layer and a second pad unit arranged on a second area of the second conductive layer exposed by the insulating film layer.

In an embodiment, the display panel may further include a display pad unit arranged at a position corresponding to the first pad unit, the main circuit board may include a main pad unit arranged at a position corresponding to the second pad unit, and the display pad unit, the first pad unit, the second pad unit, and the main pad unit may overlap each other in the plan view.

In an embodiment, the first pad unit and the second pad unit may be connected to the display pad unit and the main pad unit, respectively, by an anisotropic conductive film.

In an embodiment, the connection circuit board may be provided as a plurality of connection circuit boards, the display pad unit may be provided as a plurality of display pad units, and the plurality of display pad units may be arranged corresponding to the plurality of connection circuit boards, respectively.

In an embodiment, the connection circuit board may include a flexible printed circuit board (“FPCB”).

In an embodiment, the main circuit board may include any one of a printed circuit board (“PCB”), an FPCB, and a rigid flexible printed circuit board (“RFPCB”).

In an embodiment, the display apparatus may further include a driving chip disposed over the display panel and spaced apart from the connection circuit board.

According to one or more embodiments, a display apparatus includes: a display panel including a display area and a non-display area around the display area, a main circuit board at least partially overlapping the display panel in a plan view, and a connection circuit board at least partially overlapping the display panel, arranged between the display panel and the main circuit board, and having a pad unit arranged on opposite surfaces thereof.

In an embodiment, the connection circuit board may include a base film layer, a first conductive layer arranged on a lower surface of the base film layer, a second conductive layer arranged on an upper surface of the base film layer, and an insulating film layer exposing at least a portion of the first conductive layer and the second conductive layer.

In an embodiment, the first conductive layer and the second conductive layer may be electrically connected to each other through a through-hole defined in the base film layer.

In an embodiment, the connection circuit board may further include a first pad unit arranged under a first area of the first conductive layer exposed by the insulating film layer and a second pad unit arranged on a second area of the second conductive layer exposed by the insulating film layer, and the first area and the second area may overlap each other.

In an embodiment, the display panel may further include a display pad unit connected to the first pad unit, and the main circuit board may include a main pad unit connected to the second pad unit.

In an embodiment, the connection circuit board may include a flexible printed circuit board (FPCB), and the main circuit board may include any one of a printed circuit board (PCB), an FPCB, and a rigid flexible printed circuit board (RFPCB).

In an embodiment, the display apparatus may further include a driving chip disposed over the display panel and spaced apart from the connection circuit board.

In an embodiment, the connection circuit board and the main circuit board may be arranged overlapping one edge of the display panel in the plan view.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view of a display apparatus according to an embodiment;

FIG. 2 is a plan view of a display apparatus according to an embodiment;

FIG. 3 is an equivalent circuit diagram of a pixel included in a display apparatus according to an embodiment;

FIG. 4 is a cross-sectional view of a display area of a display panel according to an embodiment;

FIG. 5A is a cross-sectional view of a display apparatus according to an embodiment;

FIG. 5B is a cross-sectional view of a comparative example for describing a display apparatus according to an embodiment;

FIG. 6 is a cross-sectional view of a connection circuit board according to an embodiment; and

FIG. 7 is a cross-sectional view of a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may include various embodiments and modifications, and certain embodiments thereof are illustrated in the drawings and will be described herein in detail. The effects and features of the disclosure and the accomplishing methods thereof will become apparent from the embodiments described below in detail with reference to the accompanying drawings. However, the disclosure is not limited to the embodiments described below and may be embodied in various modes.

Hereinafter, embodiments will be described in detail with reference to the accompanying drawings, and in the following description, like reference numerals will denote like elements and redundant descriptions thereof will be omitted for conciseness.

It will be understood that although terms such as “first” and “second” may be used herein to describe various elements, these elements should not be limited by these terms and these terms are only used to distinguish one element from another element.

As used herein, the singular forms “a,” “an,” and “the” are intended to include the plural forms as well, unless the context clearly indicates otherwise. For example, “an element” has the same meaning as “at least one element,” unless the context clearly indicates otherwise. “At least one” is not to be construed as limiting “a” or “an.” “Or” means “and/or.”

It will be understood that terms such as “comprise,” “include,” and “have” used herein specify the presence of stated features or elements, but do not preclude the presence or addition of one or more other features or elements.

It will be understood that when a layer, region, area, component, or element is referred to as being “on” another layer, region, area, component, or element, it may be “directly on” the other layer, region, area, component, or element or may be “indirectly on” the other layer, region, area, component, or element with one or more intervening layers, regions, areas, components, or elements therebetween. Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Also, herein, the x axis, the y axis, and the z axis are not limited to three axes of the rectangular coordinate system and may be interpreted in a broader sense. For example, the x axis, the y axis, and the z axis may be perpendicular to one another or may represent different directions that are not perpendicular to one another.

Sizes of elements in the drawings may be exaggerated for convenience of description. In other words, because the sizes and thicknesses of elements in the drawings are arbitrarily illustrated for convenience of description, the disclosure is not limited thereto.

When a certain embodiment may be implemented differently, a particular process order may be performed differently from the described order. For example, two consecutively described processes may be performed substantially at the same time or may be performed in an order opposite to the described order.

It will be understood that when a layer, region, or component is referred to as being “connected to” another layer, region, or component, it may be “directly connected to” the other layer, region, or component or may be “indirectly connected to” the other layer, region, or component with one or more intervening layers, regions, or components therebetween. For example, it will be understood that when a layer, region, area, component, or element is referred to as being “electrically connected to” another layer, region, area, component, or element, it may be “directly electrically connected to” the other layer, region, area, component, or element or may be “indirectly electrically connected to” the other layer, region, area, component, or element with one or more intervening layers, regions, areas, components, or elements therebetween.

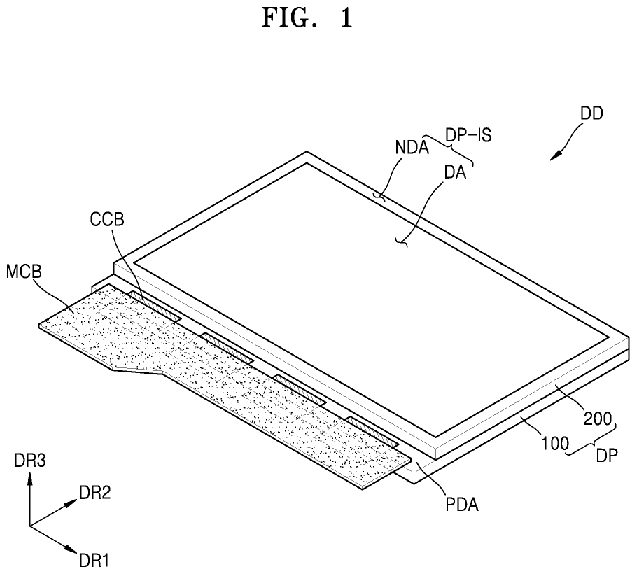

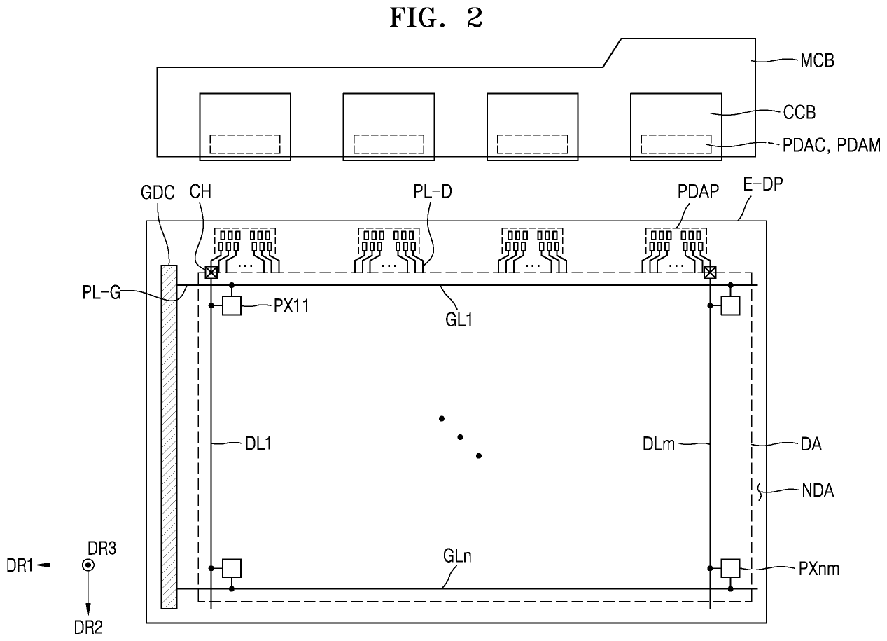

FIG. 1 is a perspective view of a display apparatus according to an embodiment, and FIG. 2 is a plan view of a display apparatus according to an embodiment.

Referring to FIGS. 1 and 2, a display apparatus DD may include a display panel DP, a connection circuit board CCB, and a main circuit board MCB.

The display panel DP may include any one of a liquid crystal display panel, a plasma display panel, an electrophoretic display panel, a microelectromechanical system (“MEMS”) display panel, an electrowetting display panel, and an organic light emitting display panel. When the display panel DP includes a liquid crystal display panel, the display apparatus DD may further include a backlight unit disposed under the display panel DP.

The display panel DP may include a first display substrate 100 and a second display substrate 200. The second display substrate 200 may face the first display substrate 100. A grayscale display layer for generating an image may be arranged between the first display substrate 100 and the second display substrate 200. The grayscale display layer may include a liquid crystal layer, an organic emission layer, or an electrophoretic layer depending on the type of the display panel.

Although not separately illustrated, the display apparatus DD may further include a window covering the display panel DP and a chassis member or a molding member combined with the window to define the appearance of the display apparatus DD.

As illustrated in FIG. 1, the display panel DP may display an image through a display surface DP-IS. The display surface DP-IS may be parallel to a plane defined by a first direction axis DR1 and a second direction axis DR2. The display surface DP-IS may include a display area DA and a non-display area NDA. The non-display area NDA may be defined along the edge of the display surface DP-IS. The display area DA may be surrounded by the non-display area NDA. However, the disclosure is not limited thereto, and the non-display area NDA may be arranged only in an area on one side adjacent to the connection circuit board CCB in another embodiment.

A third direction axis DR3 may indicate the normal direction of the display surface DP-IS, that is, the thickness direction of the display panel DP. The front surface (or upper surface) and rear surface (or lower surface) of each of the components described below may be divided by the third direction axis DR3. However, the first to third direction axes DR1, DR2, and DR3 illustrated in the present embodiment are merely examples. Hereinafter, first to third directions will be defined as directions respectively indicated by the first to third direction axes DR1, DR2, and DR3 and will be referred to as the same reference numerals as the first to third direction axes DR1, DR2, and DR3, respectively.

In an embodiment, the display panel DP is illustrated as including a flat display surface; however, the disclosure is not limited thereto. The display apparatus DD may include a curved display surface or a three-dimensional display surface in another embodiment. The three-dimensional display surface may include a plurality of display areas indicating different directions.

A signal controller (not illustrated) may be mounted on the main circuit board MCB. The signal controller may receive image data and a control signal from an external graphic controller (not illustrated). The signal controller may provide a control signal to the display panel DP. The main circuit board MCB may be connected to the display panel DP through the connection circuit board CCB. The main circuit board MCB may at least partially overlap the display panel DP in a plan view.

The connection circuit board CCB may be arranged between the display panel DP and the main circuit board MCB. The display panel DP may be attached to the lower surface of the connection circuit board CCB, and the main circuit board MCB may be attached to the upper surface of the connection circuit board CCB. The connection circuit board CCB may at least partially overlap the main circuit board MCB in a plan view. As illustrated in FIG. 1, a portion of the connection circuit board CCB may be exposed by the main circuit board MCB. Alternatively, the connection circuit board CCB may be completely covered by the main circuit board MCB.

According to an embodiment, the display panel DP may include a display pad unit PDAP, the connection circuit board CCB may include a connection pad unit PDAC, and the main circuit board MCB may include a main pad unit PDAM. The display pad unit PDAP, the connection pad unit PDAC, and the main pad unit PDAM may overlap each other in a plan view. All of the display pad unit PDAP, the connection pad unit PDAC, and the main pad unit PDAM may be arranged in a pad area PDA of FIG. 1.

The connection pad unit PDAC of the connection circuit board CCB may be connected to the display pad unit PDAP of the display panel DP and the main pad unit PDAM of the main circuit board MCB by a conductive adhesive member. The conductive adhesive member may include an anisotropic conductive film (ACF). Hereinafter, it will be described as including an anisotropic conductive film (ACF).

In the present embodiment, the display pad unit PDAP is illustrated as being disposed on the first display substrate 100; however, the disclosure is not limited thereto. In an embodiment, the display pad unit PDAP may be disposed on the second display substrate 200.

In an embodiment, the connection circuit board CCB may be provided as a plurality of connection circuit boards CCB. For example, the plurality of connection circuit boards CCB may be arranged apart from each other in the first direction DR1. The display pad unit PDAP of the display panel DP may be provided as a plurality of display pad units PDAP. The plurality of display pad units PDAP may be arranged corresponding to the plurality of connection circuit boards CCB, respectively.

FIG. 2 illustrates the arrangement relationship of signal lines GL1 to GLn, DL1 to DLm, PL-G, and PL-D and pixels PX11 to PXnm in the plan view. The signal lines GL1 to GLn, DL1 to DLm, PL-G, and PL-D may include a plurality of gate lines GL1 to GLn, a plurality of data lines DL1 to DLm, and auxiliary signal lines PL-G and PL-D.

The gate lines GL1 to GLn may extend in the first direction DR1 and may be arranged in the second direction DR2, and the plurality of data lines DL1 to DLm may insulatively intersect the plurality of gate lines GL1 to GLn. The gate lines GL1 to GLn and the data lines DL1 to DLm may be arranged overlapping the display area DA in a plan view. The auxiliary signal lines PL-G and PL-D may be arranged overlapping the non-display area NDA in a plan view, and the auxiliary signal lines PL-G and PL-D may be connected to the corresponding gate lines GL1 to GLn and data lines DL1 to DLm.

Second auxiliary signal lines PL-D connected to the data lines DL1 to DLm may be arranged on a different layer than the plurality of data lines DL1 to DLm. The data lines DL1 to DLm may be electrically connected to corresponding second auxiliary signal lines PL-D among the second auxiliary signal lines PL-D through a contact hole CH. The contact hole CH may pass through at least one insulating layer arranged between the data lines DL1 to DLm and the second auxiliary signal lines PL-D. In FIG. 2, two contact holes CH are illustrated as an example.

In an embodiment, the contact hole CH may be omitted. The data lines DL1 to DLm and the second auxiliary signal lines PL-D may be arranged on the same layer. In this case, among the data lines DL1 to DLm and the second auxiliary signal lines PL-D, the connected data line and second auxiliary signal line may be defined as one signal line. In this case, the data line and the second auxiliary signal line connected to each other may be defined as different portions of one signal line.

The pixels PX11 to PXnm may be arranged in the display area DA. The pixels PX11 to PXnm of the display apparatus may be areas capable of emitting light of certain colors, and the display apparatus may provide an image by using the light emitted from the pixels PX11 to PXnm. In an embodiment, for example, each of the pixels PX11 to PXnm may emit red light, green light, or blue light.

Each of the pixels PX11 to PXnm may further include a plurality of thin film transistors and a storage capacitor for controlling a display element. The number of thin film transistors included in one pixel may be variously modified, such as 1 to 7.

The pixels PX11 to PXnm may not be arranged in the non-display area NDA. Each of the pixels PX11 to PXnm may be connected to a corresponding gate line among the plurality of gate lines GL1 to GLn and a corresponding data line among the plurality of data lines DL1 to DLm. Each of the pixels PX11 to PXnm may include a pixel driving circuit and a display element.

In FIG. 2, the pixels PX11 to PXnm arranged in a matrix form are illustrated as an example; however, the disclosure is not limited thereto. The pixels PX11 to PXnm may be arranged in a diamond form, and in this case, the arrangement structure of the pixels PX11 to PXnm may be defined as a pentile structure in another embodiment.

A gate driving circuit GDC may be integrated into the display panel DP through an oxide silicon gate driver circuit (“OSG”) or amorphous silicon gate driver circuit (“ASG”) process. First auxiliary signal lines PL-G may be configured to receive a gate signal from the gate driving circuit GDC.

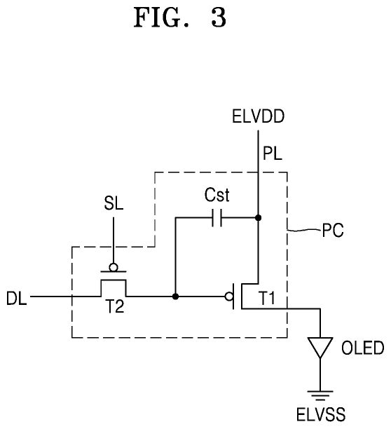

FIG. 3 is an equivalent circuit diagram of a pixel included in a display apparatus according to an embodiment. As illustrated in FIG. 3, a pixel PX may include a pixel circuit PC and an organic light emitting diode OLED electrically connected thereto.

The pixel circuit PC may include a first thin film transistor T1, a second thin film transistor T2, and a storage capacitor Cst. As a switching transistor, the second thin film transistor T2 may be connected to a scan line SL and a data line DL and may be turned on by a switching signal input from the scan line SL to transmit a data signal input from the data line DL to the first thin film transistor T1. One end of the storage capacitor Cst may be electrically connected to the second thin film transistor T2 and the other end thereof may be electrically connected to a driving voltage line PL, and the storage capacitor Cst may be configured to store a voltage corresponding to the difference between a voltage received from the second thin film transistor T2 and a driving power voltage ELVDD supplied to the driving voltage line PL.

As a driving transistor, the first thin film transistor T1 may be connected to the driving voltage line PL and the storage capacitor Cst and may be configured to control the magnitude of a driving current flowing from the driving voltage line PL through the organic light emitting diode OLED in response to a voltage value stored in the storage capacitor Cst. The organic light emitting diode OLED may emit light with a certain brightness according to the driving current. A second electrode CE of the organic light emitting diode OLED may be supplied with an electrode power voltage ELVSS.

FIG. 3 illustrates that the pixel circuit PC includes two transistors and one storage capacitor; however, the disclosure is not limited thereto. The number of transistors and the number of storage capacitors may be variously modified according to the design of the pixel circuit PC.

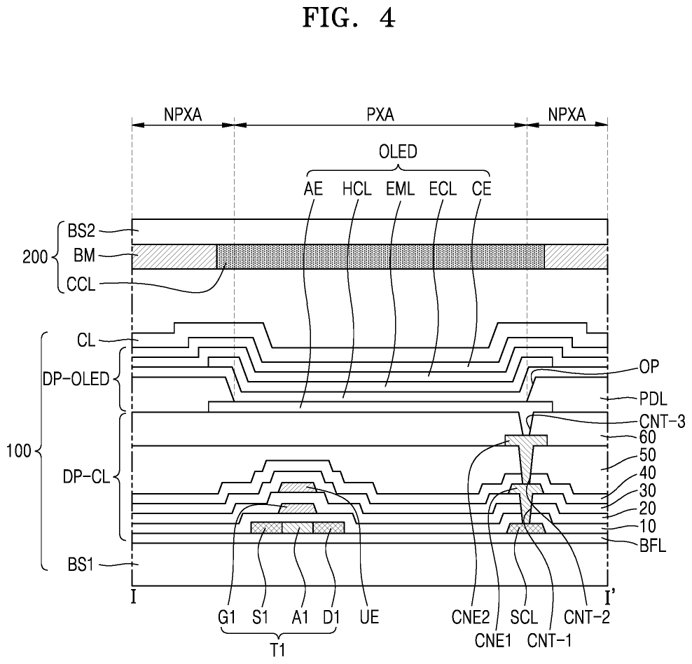

FIG. 4 is a cross-sectional view of a display area DA of a display panel DP according to an embodiment. FIG. 4 illustrates a cross-section corresponding to a pixel PX of an organic light emitting display panel.

Referring to FIG. 4, a grayscale display layer of the display panel DP according to an embodiment may include an organic emission layer. Thus, the display panel DP may include an organic light emitting display panel.

The organic light emitting display panel may include a first display substrate 100 and a second display substrate 200. The first display substrate 100 may include a first base substrate BS1, a circuit element layer DP-CL disposed over the first base substrate BS1, a display element layer DP-OLED disposed over the circuit element layer DP-CL, and a cover layer CL disposed over the display element layer DP-OLED. The second display substrate 200 may include a second base substrate BS2, and a black matrix layer BM and a color control layer CCL disposed over the second base substrate BS2.

The circuit element layer DP-CL may include a plurality of insulating layers, a semiconductor pattern, a conductive pattern, a signal line, and/or the like. An insulating layer, a semiconductor layer, and a conductive layer may be formed by coating, deposition, or the like. Thereafter, the insulating layer, the semiconductor layer, and the conductive layer may be selectively patterned by photolithography. In this way, a semiconductor pattern, a conductive pattern, a signal line, and/or the like included in the circuit element layer DP-CL and the display element layer DP-OLED may be formed.

The first base substrate BS1 may be formed of or include various materials such as glass materials, metal materials, or plastic materials. According to an embodiment, the first base substrate BS1 may be a flexible substrate and may include, for example, a polymer resin such as polyethersulphone (“PES”), polyacrylate (“PAR”), polyetherimide (“PEI”), polyethylene naphthalate (“PEN”), polyethylene terephthalate (“PET”), polyphenylene sulfide (“PPS”), polyarylate, polyimide (PI), polycarbonate (“PC”), or cellulose acetate propionate (“CAP”).

The buffer layer BFL may be disposed over the first base substrate BS1. A buffer layer BFL may be located over the first base substrate BS1 to reduce or block the penetration of foreign materials, moisture, or external air from under the first base substrate BS1 and to provide a flat surface over the first base substrate BS1. The buffer layer BFL may include an inorganic material such as oxide or nitride, an organic material, or an organic/inorganic composite and may include a single-layer or multiple-layer structure of an inorganic material and an organic material. A barrier layer (not illustrated) for blocking the penetration of external air may be further included between the buffer layer BFL and the first base substrate BS1. In some embodiments, the buffer layer BFL may include silicon oxide (SiO₂) or silicon nitride (SiNₓ). The buffer layer BFL may improve the bonding force between the first base substrate BS1 and the semiconductor pattern.

A semiconductor pattern may be disposed over the buffer layer BFL. The semiconductor pattern may include polysilicon. However, the disclosure is not limited thereto and the semiconductor pattern may include amorphous silicon or metal oxide.

The semiconductor pattern may include a doped area and an undoped area. The doped area may be doped with N-type dopants or P-type dopants. A P-type transistor may include a doped area doped with P-type dopants.

The doped area may have a higher conductivity than the undoped area and may substantially function as an electrode or a signal line. The undoped area may substantially correspond to an active area (or channel) of the transistor. In other words, a portion of the semiconductor pattern may be an active area of the transistor, another portion thereof may be a source or drain of the transistor, and another portion thereof may be a connection electrode or a connection signal line.

The first thin film transistor T1 may be disposed over the buffer layer BFL. A source S1, an active area A1, and a drain D1 of the first thin film transistor T1 may be formed from the semiconductor pattern. FIG. 4 illustrates a portion of a connection signal line SCL formed from the semiconductor pattern. Although not separately illustrated, the connection signal line SCL may be connected to the drain D1 of the first thin film transistor T1 in the plan view.

First to sixth insulating layers 10 to 60 may be disposed over the buffer layer BFL. The first to sixth insulating layers 10 to 60 may be inorganic layers or organic layers. A gate G1 may be disposed over the first insulating layer 10. An upper electrode UE may be disposed over the second insulating layer 20. A first connection electrode CNE1 may be disposed over the third insulating layer 30. The first connection electrode CNE1 may be connected to the connection signal line SCL through a contact hole CNT-1 passing through the first to third insulating layers 10 to 30. A second connection electrode CNE2 may be disposed over the fifth insulating layer 50. The second connection electrode CNE2 may be connected to the first connection electrode CNE1 through a contact hole CNT-2 passing through the fourth insulating layer 40 and the fifth insulating layer 50.

An organic light emitting diode OLED may be disposed as a light emitting element over the sixth insulating layer 60. A first electrode AE may be disposed over the sixth insulating layer 60. The first electrode AE may be connected to the second connection electrode CNE2 through a contact hole CNT-3 passing through the sixth insulating layer 60.

The display element layer DP-OLED may include an organic light emitting diode OLED and a pixel definition layer PDL. In an embodiment, for example, the pixel definition layer PDL may be an organic layer. The organic light emitting diode OLED may include a first electrode AE, a hole control layer HCL, an emission layer EML, an electron control layer ECL, and a second electrode CE.

The first electrode AE may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. In another embodiment, the first electrode AE may further include a conductive oxide layer over and/or under the above reflective layer. The conductive oxide layer may include indium tin oxide (“ITO”), indium zinc oxide (“IZO”), zinc oxide (ZnO), indium oxide (In₂O₃), indium gallium oxide (“IGO”), and/or aluminum zinc oxide (“AZO”). In an embodiment, the first electrode AE may include a three-layer structure of ITO layer/Ag layer/ITO layer.

The pixel definition layer PDL may be disposed over the sixth insulating layer 60. The pixel definition layer PDL may include an opening portion OP (hereinafter referred to as an emission opening portion) defined therein. The emission opening portion OP may expose at least a portion of the first electrode AE. The pixel definition layer PDL may define the pixel PX by including the emission opening portion OP through which a center portion of the first electrode AE is exposed. Also, the pixel definition layer PDL may increase the distance between the edge of the first electrode AE and the second electrode CE, thereby preventing an arc or the like from occurring therebetween. In an embodiment, the pixel definition layer PDL may be formed of or include, for example, an organic material such as polyimide or hexamethyldisiloxane (“HMDSO”). In another embodiment, the pixel definition layer PDL may have a black color. The pixel definition layer PDL may include a black component (black coloring agent). The pixel definition layer PDL may include a black dye or a black pigment mixed with a base resin.

FIG. 4 illustrates an emission area PXA and a non-emission area NPXA adjacent to the emission area PXA. Substantially, the emission area PXA may be defined to correspond to an area of the first electrode AE exposed by the emission opening portion OP.

The hole control layer HCL may be commonly arranged in the emission area PXA and the non-emission area NPXA. The hole control layer HCL may include a hole transport layer and may further include a hole injection layer. The emission layer EML may be disposed over the hole control layer HCL. The emission layer EML may be arranged in an area corresponding to the emission opening portion OP.

The electronic control layer ECL may be disposed over the emission layer EML. The electron control layer ECL may include an electron transport layer and may further include an electron injection layer. The second electrode CE may be disposed over the electronic control layer ECL.

The second electrode CE may be arranged over the display area DA and the non-display area NDA and may be disposed over the pixel definition layer PDL. The second electrode CE may be integrally formed in a plurality of organic light emitting diodes OLED to correspond to a plurality of first electrodes AE. The second electrode CE may include a conductive material having a low work function. In an embodiment, for example, the second electrode CE may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the second electrode CE may further include a layer such as ITO, IZO, ZnO, or In₂O₃ over the (semi) transparent layer including the above material.

The cover layer CL may be disposed over the second electrode CE. The cover layer CL may include a plurality of thin films. As in the present embodiment, the cover layer CL may include a capping layer and a thin film encapsulation layer. The capping layer may be disposed over the second electrode CE to improve the light efficiency. The capping layer may include an organic material, an inorganic material, or a mixture thereof.

The second base substrate BS2 may be arranged apart from the cover layer CL. The second base substrate BS2 may include any one of a glass substrate, a plastic substrate, and a substrate including polyimide (PI).

The color control layer CCL may transmit first-color light or convert the first-color light into second-color light or third-color light according to the color of light provided by the organic light emitting diode OLED. The color control layer CCL may include quantum dots. In this case, the first-color light may be blue light.

The black matrix layer BM may overlap the non-emission area NPXA in a plan view. The black matrix layer BM may have a black color. The black matrix layer BM may include a material that absorbs light; however, the disclosure is not limited thereto.

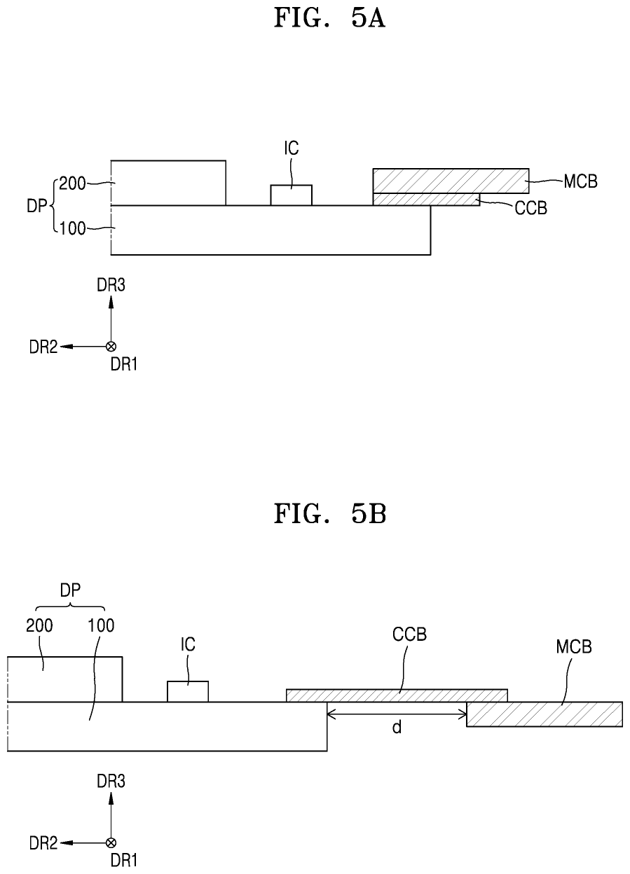

FIG. 5A is a cross-sectional view of a display apparatus according to an embodiment, and FIG. 5B is a cross-sectional view of a comparative example for describing a display apparatus according to an embodiment.

The display apparatus according to an embodiment may include a display panel DP, a connection circuit board CCB, a main circuit board MCB, and a driving chip IC. The driving chip IC may transmit a signal received from the main circuit board MCB to the display panel DP. The driving chip IC may be arranged apart from the connection circuit board CCB. In the present embodiment, the driving chip IC is illustrated as being mounted on the display panel DP; however, the disclosure is not limited thereto. The driving chip IC may be mounted on the connection circuit board CCB or mounted on the main circuit board MCB in another embodiment.

Referring to FIG. 5A, the connection circuit board CCB may be arranged between the display panel DP and the main circuit board MCB. In the display apparatus, the display panel DP, the connection circuit board CCB, and the main circuit board MCB may be stacked in the thickness direction (e.g., the third direction DR3) of the display apparatus DD. That is, the display panel DP and the main circuit board MCB may be arranged on opposite surfaces of the connection circuit board CCB, respectively. In an embodiment, the display panel DP may be attached to the lower surface of the connection circuit board CCB, and the main circuit board MCB may be attached to the upper surface of the connection circuit board CCB.

Referring to FIG. 5B, in the comparative example, the main circuit board MCB and the display panel DP may be attached to the same surface (e.g., lower surface) of the connection circuit board CCB. Accordingly, the main circuit board MCB and the display panel DP may not overlap each other in a plan view. The edge of the main circuit board MCB and the edge of the display panel DP may be spaced apart from each other by a tolerance interval d in the plan view. The tolerance interval d may be a desirable tolerance in a process for avoiding the interference between the main circuit board MCB and the display panel DP.

Referring back to FIG. 5A, unlike in the comparative example of FIG. 5B, in the display apparatus DD according to an embodiment, the display panel DP, the connection circuit board CCB, and the main circuit board MCB may partially overlap each other in a plan view, and thus, there may be no tolerance interval d in the plan view. Accordingly, the dead space of the display apparatus DD may be effectively reduced.

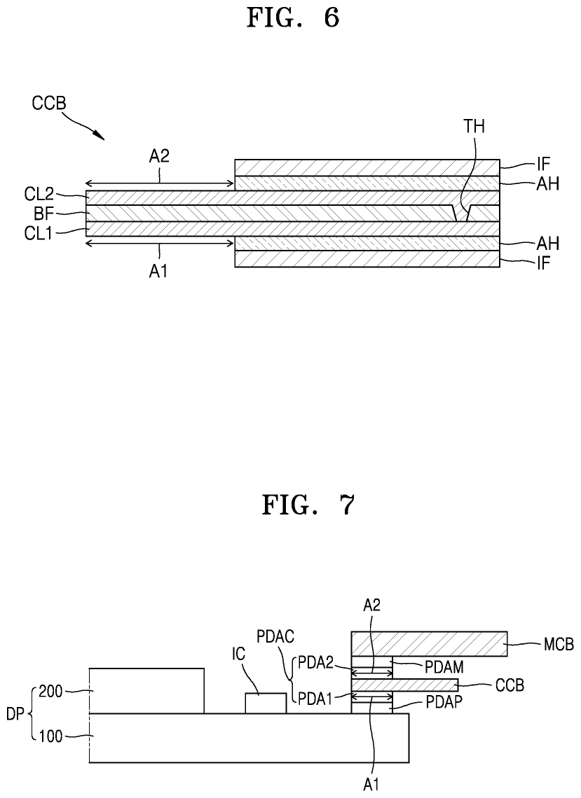

Also, because the pad units PDAP, PDAC, and PDAM for connection between the display panel DP, the connection circuit board CCB, and the main circuit board MCB may overlap each other in a plan view and thus may be pressed together, a process operation for the connection may be simplified. Details thereof will be described below with reference to FIGS. 6 and 7.

In an embodiment, the main circuit board MCB may include any one of a printed circuit board (PCB), a flexible printed circuit board (FPCB), and a rigid flexible printed circuit board (RFPCB). Particularly, when the main circuit board MCB includes an FPCB or an RFPCB that is relatively thin, a thickness problem that may occur when the main circuit board MCB is stacked over the display panel DP may be prevented.

FIG. 6 is a cross-sectional view of a connection circuit board CCB according to an embodiment. FIG. 7 is a cross-sectional view of a display apparatus DD according to an embodiment. In an embodiment, the connection circuit board CCB may include an FPCB.

Referring to FIG. 6, the connection circuit board CCB may include a base film layer BF, first and second conductive layers CL1 and CL2, an adhesive material AH, and an insulating film layer IF.

Opposite surfaces (i.e., lower surface and upper surface) of the base film layer BF may be covered with the first conductive layer CL1 and the second conductive layer CL2, respectively. The base film layer BF may prevent a crack in the first conductive layer CL1 and the second conductive layer CL2. The base film layer BF may include a polyimide (PI) film.

The first conductive layer CL1 may be arranged on the lower surface of the base film layer BF, and the second conductive layer CL2 may be arranged on the upper surface of the base film layer BF. The first conductive layer CL1 and the second conductive layer CL2 may include a conductive material. In an embodiment, for example, the first conductive layer CL1 and the second conductive layer CL2 may include copper (Cu). The connection circuit board CCB may define a through-hole TH therein for electrically connecting the first conductive layer CL1 and the second conductive layer CL2 to each other. The through-hole TH may be filled with a conductor such as a plating material to transfer electric signals between the first conductive layer CL1 and the second conductive layer CL2.

The insulating film layer IF may be adhered to the first conductive layer CL1 and the second conductive layer CL2 by the adhesive material AH. The insulating film layer IF may cover a portion of the first conductive layer CL1 and the second conductive layer CL2. Accordingly, one surface of each of the first conductive layer CL1 and the second conductive layer CL2 may contact the base film layer BF, and the other surface thereof may contact the insulating film layer IF. The insulating film layer IF may maintain the rigidity of the connection circuit board CCB and may protect an electric signal from the outside. The insulating film layer IF may include a polyimide (PI) film.

The insulating film layer IF may expose a portion of the first conductive layer CL1 and the second conductive layer CL2. The insulating film layer IF may define a first area A1 by exposing a portion of the first conductive layer CL1. The insulating film layer IF may define a second area A2 by exposing a portion of the second conductive layer CL2. The first area A1 and the second area A2 may overlap each other in a plan view.

Referring to FIG. 7, the display panel DP may include a display pad unit PDAP, the main circuit board MCB may include a main pad unit PDAM, and the connection circuit board CCB may include a connection pad unit PDAC. The connection pad unit PDAC may include a first pad unit PDA1 disposed under the first conductive layer CL1 and a second pad unit PDA2 disposed on the second conductive layer CL2.

Referring to FIGS. 6 and 7 together, the first pad unit PDA1 of the connection pad unit PDAC to be pressed with the display pad unit PDAP of the display panel DP may be disposed under the first area A1 of the first conductive layer CL1. The second pad unit PDA2 of the connection pad unit PDAC to contact the main pad unit PDAM of the main circuit board MCB may be disposed on the second area A2 of the second conductive layer CL2.

In an embodiment, the display pad unit PDAP may overlap the first pad unit PDA1, and the second pad unit PDA2 may overlap the main pad unit PDAM in a plan view. Alternatively, the display pad unit PDAP, the first pad unit PDA1, the second pad unit PDA2, and the main pad unit PDAM may overlap each other in a plan view.

The display pad unit PDAP may be electrically connected to the first pad unit PDA1 through an anisotropic conductive film (ACF) therebetween. The main pad unit PDAM may be electrically connected to the second pad unit PDA2 through an anisotropic conductive film (ACF) therebetween. The anisotropic conductive film (ACF) may be arranged between the display pad unit PDAP and the first pad unit PDA1 and between the main pad unit PDAM and the second pad unit PDA2 to combine the display panel DP, the connection circuit board CCB, and the main circuit board MCB through a pressing process.

In an embodiment, because the connection circuit board CCB is arranged between the display panel DP and the main circuit board MCB, the display panel DP, the connection circuit board CCB, and the main circuit board MCB may be pressed together through the above pressing process. Accordingly, a process operation for connecting each pad unit may be simplified.

The connection circuit board CCB may be attached to the display panel DP and then the main circuit board MCB may be attached to the connection circuit board CCB, or the main circuit board MCB may be attached to the connection circuit board CCB and then the connection circuit board CCB may be attached to the display panel DP. In the above drawings, the connection circuit board CCB is illustrated as being disposed over the first display substrate 100; however, the disclosure is not limited thereto. In an embodiment, the connection circuit board CCB may be disposed over the second display substrate 200.

Because the display apparatus DD according to embodiments includes a display panel DP including a plurality of pixels PX11 to PXnm, a main circuit board MCB configured to transmit a signal to the display panel DP, and a connection circuit board CCB connecting the display panel DP with the main circuit board MCB and the connection circuit board CCB is arranged between the display panel DP and the main circuit board MCB, the dead space (e.g., at least the tolerance interval d of FIG. 5B) of the display apparatus may be effectively reduced. Also, because a connection pad unit PDAC is formed on opposite surfaces of the connection circuit board CCB, the manufacturing process thereof may be simplified.

Even though a case that the display panel DP is attached to the lower surface of the connection circuit board CCB and the main circuit board MCB is attached to the upper surface of the connection circuit board CCB is illustrated in the above embodiment, the disclosure is not limited thereto. In another embodiment, the display panel DP may be attached to the upper surface of the connection circuit board CCB and the main circuit board MCB may be attached to the lower surface of the connection circuit board CCB.

According to an embodiment described above, because a connection circuit board is arranged between a display panel and a main circuit board, a dead space may be minimized and a high-quality image may be implemented. However, these effects are merely examples and the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display panel comprising a plurality of pixels;
a main circuit board configured to transmit a signal to the display panel; and
a connection circuit board arranged between the display panel and the main circuit board and having a lower surface to which one of the display panel and the main circuit board is attached and an upper surface to which another one of the display panel and the main circuit board is attached.

2. The display apparatus of claim 1, wherein the display panel and the main circuit board at least partially overlap each other in a plan view.

3. The display apparatus of claim 1, wherein the connection circuit board comprises a base film layer, a first conductive layer arranged on a lower surface of the base film layer, a second conductive layer arranged on an upper surface of the base film layer, and an insulating film layer exposing at least a portion of the first conductive layer and the second conductive layer.

4. The display apparatus of claim 3, wherein the first conductive layer and the second conductive layer are electrically connected to each other through a through-hole defined in the base film layer.

5. The display apparatus of claim 3, wherein the base film layer and the insulating film layer comprise polyimide (PI), and
the first conductive layer and the second conductive layer comprise copper (Cu).

6. The display apparatus of claim 3, wherein the connection circuit board further comprises a first pad unit arranged under a first area of the first conductive layer exposed by the insulating film layer and a second pad unit arranged on a second area of the second conductive layer exposed by the insulating film layer.

7. The display apparatus of claim 6, wherein the display panel further comprises a display pad unit arranged at a position corresponding to the first pad unit,
the main circuit board comprises a main pad unit arranged at a position corresponding to the second pad unit, and
the display pad unit, the first pad unit, the second pad unit, and the main pad unit overlap each other in a plan view.

8. The display apparatus of claim 7, wherein the first pad unit and the second pad unit are connected to the display pad unit and the main pad unit, respectively, by an anisotropic conductive film.

9. The display apparatus of claim 7, wherein the connection circuit board is provided as a plurality, the display pad unit is provided as a plurality, and the plurality of display pad units are arranged corresponding to the plurality of connection circuit boards, respectively.

10. The display apparatus of claim 1, wherein the connection circuit board comprises a flexible printed circuit board (FPCB).

11. The display apparatus of claim 1, wherein the main circuit board comprises any one of a printed circuit board (PCB), a flexible printed circuit board (FPCB), and a rigid flexible printed circuit board (RFPCB).

12. The display apparatus of claim 1, further comprising a driving chip disposed over the display panel and spaced apart from the connection circuit board.

13. A display apparatus comprising:
a display panel comprising a display area and a non-display area around the display area;
a main circuit board at least partially overlapping the display panel in a plan view; and
a connection circuit board at least partially overlapping the display panel, arranged between the display panel and the main circuit board, and having a pad unit arranged on opposite surfaces thereof.

14. The display apparatus of claim 13, wherein the connection circuit board comprises a base film layer, a first conductive layer arranged on a lower surface of the base film layer, a second conductive layer arranged on an upper surface of the base film layer, and an insulating film layer exposing at least a portion of the first conductive layer and the second conductive layer.

15. The display apparatus of claim 14, wherein the first conductive layer and the second conductive layer are electrically connected to each other through a through-hole defined in the base film layer.

16. The display apparatus of claim 14, wherein the connection circuit board further comprises a first pad unit arranged under a first area of the first conductive layer exposed by the insulating film layer and a second pad unit arranged on a second area of the second conductive layer exposed by the insulating film layer, and
the first area and the second area overlap each other.

17. The display apparatus of claim 16, wherein the display panel further comprises a display pad unit connected to the first pad unit, and
the main circuit board comprises a main pad unit connected to the second pad unit.

18. The display apparatus of claim 13, wherein the connection circuit board comprises a flexible printed circuit board (FPCB), and
the main circuit board comprises any one of a printed circuit board (PCB), an FPCB, and a rigid flexible printed circuit board (RFPCB).

19. The display apparatus of claim 13, further comprising a driving chip disposed over the display panel and spaced apart from the connection circuit board.

20. The display apparatus of claim 13, wherein the connection circuit board and the main circuit board are arranged overlapping one edge of the display panel in the plan view.
